(19) United States
(12) Patent Application Publication
(10) Pub. No.: US 2005/0248975 A1
(43) Pub. Date: Nov. 10, 2005

(54) Semiconductor storage device and its manufacturing method

(75) Inventor: Toru Ozaki, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/951,673

(22) Filed: Sep. 29, 2004

(30) Foreign Application Priority Data
May 7, 2004 (JP) 2004-138684

(51) Int. Cl. G11C 11/22

(52) U.S. Cl. 365/145

(57) ABSTRACT

A semiconductor storage device comprises a semiconductor substrate; a memory cell block including a plurality of transistors formed on the semiconductor substrate, said plurality of transistors being connected in series by serial connection of a source and a drain of two neighboring transistors; first electrodes which are electrically connected to the source or drain of two neighboring transistors; a ferroelectric film deposited on sidewalls of the first electrodes to retain a gap in a central portion between two neighboring first electrodes; and second electrodes buried in the gaps and insulated from the electrodes of the transistors.

### CROSS-REFERENCE TO RELATED APPLICATION

This application is based upon and claims the benefit of priority from the prior Japanese Patent Application No. 2004-138684, filed on May 7, 2004, the entire contents of which are incorporated herein by reference.

### BACKGROUND OF THE INVENTION

1. Field of the Invention

The present invention relates to a semiconductor storage device and its manufacturing method.

2. Background Art

FIGS. 20A and 20B show a conventional memory which consists of series connected memory cells each having a transistor (T) having a source terminal and a drain terminal and a ferroelectric capacitor (C) inbetween these two terminals (hereafter named “series connected TC unit type ferroelectric RAM (FeRAM)”). FIG. 20A is a plan view of the conventional FeRAM, and FIG. 20B is a cross-sectional view taken along the X-X line of FIG. 20A. Memory cell transistors CT (hereafter referred to as “cell transistors CT”) and a selector transistor ST are formed on a semiconductor substrate 10 in serial connection. A source or drain diffusion layer 20 of each cell transistor CT is connected to a capacitor electrode 60 via a plug 50. A ferroelectric film 70 fills the space between every two adjacent capacitor electrodes 60. The ferroelectric film 70 is polarized by a voltage applied to the capacitor electrodes 60, and can hold data as a part of the capacitor CP. Bit lines BL are formed above the ferroelectric film 70, and gates 30 of a cell transistor CT and selector transistor ST function as word lines WL.

The unit including a group of cell transistors CT serially connected as explained above and a group of capacitors CP connected to these cell transistors is regarded a memory cell block CB (hereafter referred to as a “cell block CB”). The series connected TC unit type ferroelectric RAM includes a number of cell blocks CB connected to a sense amplifier (not shown). Upon read/write operation, a certain cell block CB is selected the selector transistor ST, and a certain capacitor CP is selected by its cell transistor (Japanese Patent Laid-open Publications No. JP2002-299572 and No. JP2002-289797.

In FeRAM of this type, it is important that the ferroelectric film is stable in quantity of polarization. If the quantity of polarization of the ferroelectric film 70 varies largely, the sense amplifier cannot detect data accurately.

However, distances D₀, D₁ and D₂ between capacitor electrodes 60 vary by 20˜30% of the minimum processible measure in the manufacturing process of the FeRAM. This means that the ferroelectric film 70 varies in thickness by 20˜30%. Therefore, even with the same voltage being applied to the capacitor electrode 60, electric field applied to the ferroelectric film 70 varies. It results in inviting the problem that the quantity of polarization of the ferroelectric film 70 varies. Further, operation voltage applied to the capacitor electrode 60 to polarize the ferroelectric film 70 is normally set to a level near the boundary between the non-saturated region and the saturated region of the quantity of polarization of the ferroelectric film 70. Therefore, once the ferroelectric film 70 varies in thickness, the quantity of polarization of the ferroelectric film 70 varies largely.

Further, operation voltage of conventional FeRAM is higher than operation voltages of the other most advanced semiconductor storage devices. If the ferroelectric film 70 is thick, operation voltage of FeRAM has to be increased to ensure a sufficient quantity of polarization. Therefore, it is preferable that the ferroelectric film 70 is thin. However, thickness of the ferroelectric film 70 is determined by the distance between two neighboring capacitor electrodes 60. Therefore, it has been impossible to reduce the thickness of the ferroelectric film 70 thinner than the minimum processible measure in the manufacturing process of FeRAM. As a result, conventional FeRAM is not suitable for operation under a reduced voltage.

It is therefore desirable to realize a semiconductor storage device having a ferroelectric film reduced in variety of thickness and sufficiently operable even under a reduced voltage and to realize a manufacturing method thereof.

### SUMMARY OF THE INVENTION

A semiconductor storage device according to an embodiment of the invention comprises a semiconductor substrate; a memory cell block including a plurality of transistors formed on the semiconductor substrate, said plurality of transistors being connected in series by serial connection of a source and a drain of two neighboring transistors; first electrodes which are electrically connected to the source or drain of two neighboring transistors; a ferroelectric film deposited on sidewalls of the first electrodes to retain a gap in a central portion between two neighboring first electrodes; and second electrodes buried in the gaps and insulated from the electrodes of the transistors.

A manufacturing method of a semiconductor storage device according to an embodiment of the invention comprises: forming a memory cell block including a plurality of transistors which are connected in series by connection of a source and a drain of neighboring transistors; forming first electrodes connected to the source or the drain of neighboring transistors; depositing a ferroelectric film on sidewalls of the first electrodes so as not to fill the space between the neighboring first electrodes but to retain a gap in a central portion between the neighboring first electrodes; and burying the gaps with a second conductive material so that the second conductive material in each gap is insulated from the electrodes of the transistors.

### BRIEF DESCRIPTION OF THE DRAWINGS

FIG. 1A is a plan view of a FeRAM 100 according to the first embodiment of the invention;

FIG. 1B is a cross-sectional view of the FeRAM according to the first embodiment of the invention;

FIG. 2A is a plan view showing a manufacturing method of the FeRAM 100 according to the first embodiment;

FIG. 2B is a cross-sectional view showing the manufacturing method of the FeRAM 100 according to the first embodiment;

FIG. 3A is a plan view showing the FeRAM 100 in the manufacturing process subsequent to the process of FIGS. 2A and 2B;

FIG. 3B is a cross-sectional view showing the FeRAM 100 in the manufacturing process subsequent to the process of FIGS. 2A and 2B;

FIG. 4A is a plan view showing the FeRAM 100 in the manufacturing process subsequent to the process of FIGS. 3A and 3B;

FIG. 4B is a cross-sectional view showing the FeRAM 100 in the manufacturing process subsequent to the process of FIGS. 3A and 3B;

FIG. 5A is a plan view showing the FeRAM 100 in the manufacturing process subsequent to the process of FIGS. 4A and 4B;

FIG. 5B is a cross-sectional view showing the FeRAM 100 in the manufacturing process subsequent to the process of FIGS. 4A and 4B;

FIG. 6 is a cross-sectional view of the FeRAM 100 in the process subsequent to the process of FIGS. 5A and 5B;

FIG. 7A is a plan view of a FeRAM 200 according to the second embodiment of the invention;

FIG. 7B is a cross-sectional view of the FeRAM 200 according to the second embodiment of the invention;

FIG. 8A is a plan view showing a manufacturing method of the FeRAM 200 according to the second embodiment;

FIG. 8B is a cross-sectional view showing the manufacturing method of the FeRAM 200 according to the second embodiment;

FIG. 9A is a plan view of the FeRAM 200 in the manufacturing process subsequent to the process of FIGS. 8A and 8B;

FIG. 9B is a cross-sectional view of the FeRAM 200 in the manufacturing process subsequent to the process of FIGS. 8A and 8B;

FIG. 10 is a cross-sectional view of the FeRAM 200 in the process subsequent to the process of FIGS. 9A and 9B;

FIG. 11A is a plan view of the FeRAM 200 in the manufacturing process subsequent to the process of FIG. 10;

FIG. 11B is a cross-sectional view of the FeRAM 200 in the manufacturing process subsequent to the process of FIG. 10;

FIG. 12A is a plan view of the FeRAM 200 in the manufacturing process subsequent to the process of FIGS. 11A and 11B;

FIG. 12B is a cross-sectional view of the FeRAM 200 in the manufacturing process subsequent to the process of FIGS. 11A and 11B;

FIG. 13A is a plan view of the FeRAM 200 in the manufacturing process subsequent to the process of FIGS. 12A and 12B;

FIG. 13B is a cross-sectional view of the FeRAM 200 in the manufacturing process subsequent to the process of FIGS. 12A and 12B;

FIG. 14 is a cross-sectional view of the FeRAM 200 in the process subsequent to the process of FIGS. 13A and 13B;

FIG. 15A is a plan view of a FeRAM 300 according to the third embodiment of the invention;

FIG. 15B is a cross-sectional view of the FeRAM 300 according to the third embodiment of the invention;

FIG. 16A is a plan view of a FeRAM 400 according to the fourth embodiment of the invention;

FIG. 16B is a cross-sectional view of the FeRAM 400 according to the fourth embodiment of the invention;

FIG. 17A is a plan view of a FeRAM 500 according to the fifth embodiment of the invention;

FIG. 17B is a cross-sectional view of the FeRAM 500 according to the fifth embodiment of the invention;

FIG. 18A is a plan view of a FeRAM 600 according to the sixth embodiment of the invention;

FIG. 18B is a cross-sectional view of the FeRAM 600 according to the sixth embodiment of the invention;

FIG. 19A is a plan view of a FeRAM 700 according to the seventh embodiment of the invention;

FIG. 19B is a cross-sectional view of the FeRAM 700 according to the seventh embodiment of the invention;

FIG. 20A is a plan view of a conventional FeRAM; and

FIG. 20B is a cross-sectional view of the conventional FeRAM.

### DETAILED DESCRIPTION OF THE INVENTION

Some embodiments of the invention will now be explained below with reference to the drawings. These embodiments should not be construed to limit the invention. For easier understanding, the drawings illustrate components in rough sketches.

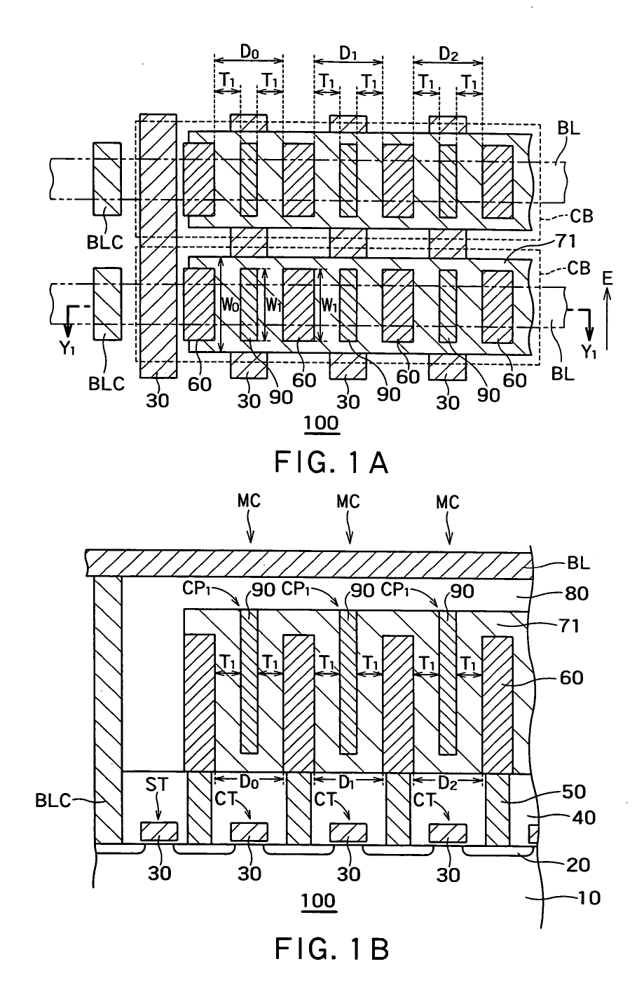

FIGS. 1A and 1B are a plan view of a FeRAM according to the first embodiment of the invention and a cross-sectional view taken along the Y1-Y1 line of the plan view. The FeRAM 100 is a memory which consists of series connected memory cells each having a transistor having a source terminal and a drain terminal and a ferroelectric capacitor inbetween said two terminals, hereafter named “series connected TC unit type ferroelectric RAM”. The FeRAM 100 includes a semiconductor substrate 10, memory cell transistors CT (hereafter named “cell transistors CT”), selector transistors ST, interlayer insulating film 40, plugs 50, capacitor electrodes 60, ferroelectric films 71, interlayer insulating film 80, floating electrodes 90 and bit lines BL.

A memory cell block CB (hereafter simply called “cell block CB”) includes a plurality of cell transistors CT and a selector transistor ST formed on the semiconductor substrate. Source or drain diffusion layers 20 of the cell transistors CT and the selector transistor ST are formed on the surface of the semiconductor substrate 10, and they are connected to the capacitor electrodes 60 via the plugs 50.

In each cell block CB, every two neighboring cell transistors CT share a common layer as their source and drain, and all these cell transistors CT are connected in series by these layers. The selector transistor ST is formed at one end of each cell block CB. The selector transistor ST is connected to the cell transistors CT in the common cell block CB through one of diffusion layers, and connected to a bit line contact BLC through the other diffusion layer. At the other end of each cell block CB, a plate line (not shown) for determining the potential of the semiconductor substrate 10 is formed. The diffusion layer 20 at the other end of the cell block CB, for example, may be used as the plate line.

The ferroelectric film 71 is deposited on sidewalls of neighboring capacitor electrodes 60 by an approximately uniform thickness T₁. The ferroelectric film 71 is deposited by a method excellent in step coverage, such as MOCVD (Metal Organic Chemical Vapor Deposition). A gap is retained in a central portion between every two neighboring capacitor electrodes 60, and it is filled with a floating electrode 90. To retain the gap in the central portion between the capacitor electrodes 60, the ferroelectric film 71 is deposited not to bury the full space between the capacitor electrodes 60. The floating electrodes 90 are insulated in terms of direct current from the cell transistors CT, selector transistors ST, bit lines BL and semiconductor substrate 10. The ferroelectric film 71 may be made of, for example, PZT (Pb(Ti, Zr)O₃), SBT(SrBi₂Ta₂O₉) or BLT((Bi, La)₄Ti₃O₁₂). The floating electrodes 90 may be made of the same material as that of the capacitor electrodes 60, such as, lutetium (Lu), iridium (Ir), iridium oxide (IrO₂), platinum (Pt), SRO (SrRuO₃), or the like.

Thickness T₁ of the ferroelectric film 71 must be less than ½ of the distance between neighboring capacitor electrodes 60 to retain the gap for forming the floating electrode 90 only in the central portion between the capacitor electrodes 60. Thus, the thickness T₁ must satisfy T₁<D₀/2, T₁<D₁/2 and T₁<D₂/2 in FIGS. 1A and 1B.

In addition, when E is the direction normal to the alignment direction of the cell transistors CT and the selector transistor, width W₀ of each ferroelectric film 71 in the direction E is wider than the width W₁ of the capacitor electrodes 60 and the floating electrodes 90. Thus, even if the ferroelectric film 71 are offset in position more or less relative to the capacitor electrodes 60 and the floating electrodes 90, areas of the ferroelectric films 71 opposed to the capacitor electrodes and the floating electrodes 90 do not vary. This means that the ferroelectric film 71 can maintain a constant quantity of polarization through out a cell block CB.

One floating electrode 90, ferroelectric film 71 adjacent to side surfaces thereof and two capacitor electrodes 60 nearest to the floating electrode 90 via the ferroelectric film 71 make one capacitor CP₁. One capacitor CP₁ and one cell transistor CT function as a one-bit memory cell MC. FIGS. 1A and 1B illustrate a part including three memory cells MC corresponding to three bits.

Each cell block CB includes 8 memory cells (8 bits) or 16 memory cells (16 bits). The number of memory cells MC is not limitative. However, if the cell block includes too many memory cells MC, transistors CT remote from the bit line contact BLC will not be supplied with a sufficient voltage. In this sense, there is an upper limit of the number of memory cells MC.

An interlayer insulating film 80 is deposited on the capacitors CP₁. Bit lines BL are formed on the interlayer insulating film 80. In this embodiment, gates 30 of cell transistors CT and the selector transistor ST serve as word lines WL. Thus, the selector transistor ST can select a cell block CB, and each cell transistor CT can select its associated memory cell MC.

When a voltage is applied to a capacitor electrode 60 through a selector transistor ST and a cell transistor CT, an electric field is applied to the ferroelectric film 71. As a result, the ferroelectric film 71 is polarized and can hold data. Once the ferroelectric film 71 is polarized, the polarization of the ferroelectric film 71 is maintained even after the voltage to the capacitor electrode 60 is interrupted. Therefore, each memory cell MC functions as a nonvolatile memory.

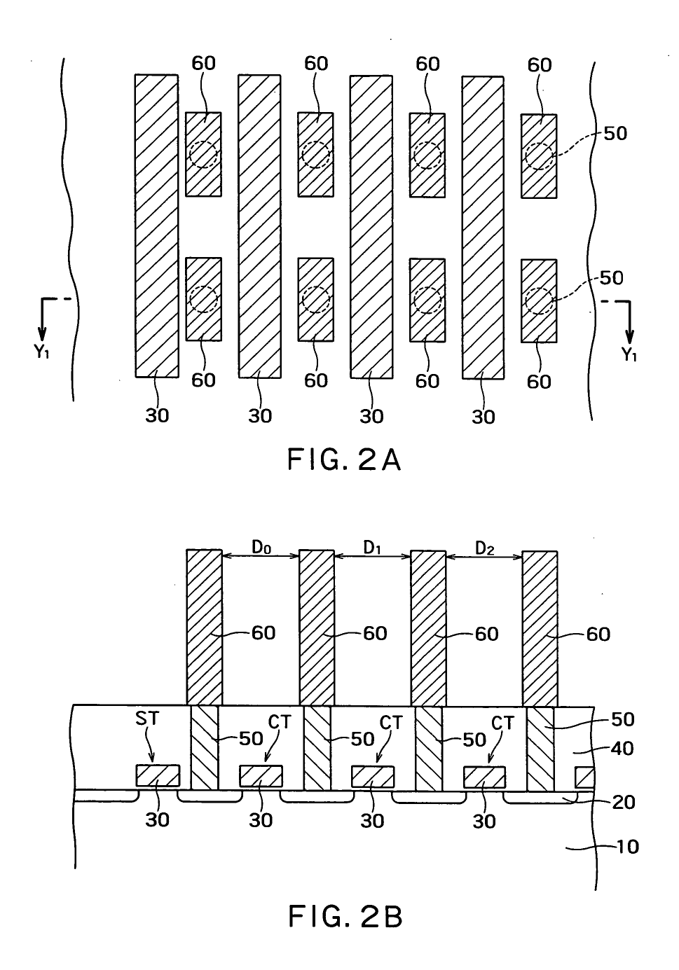

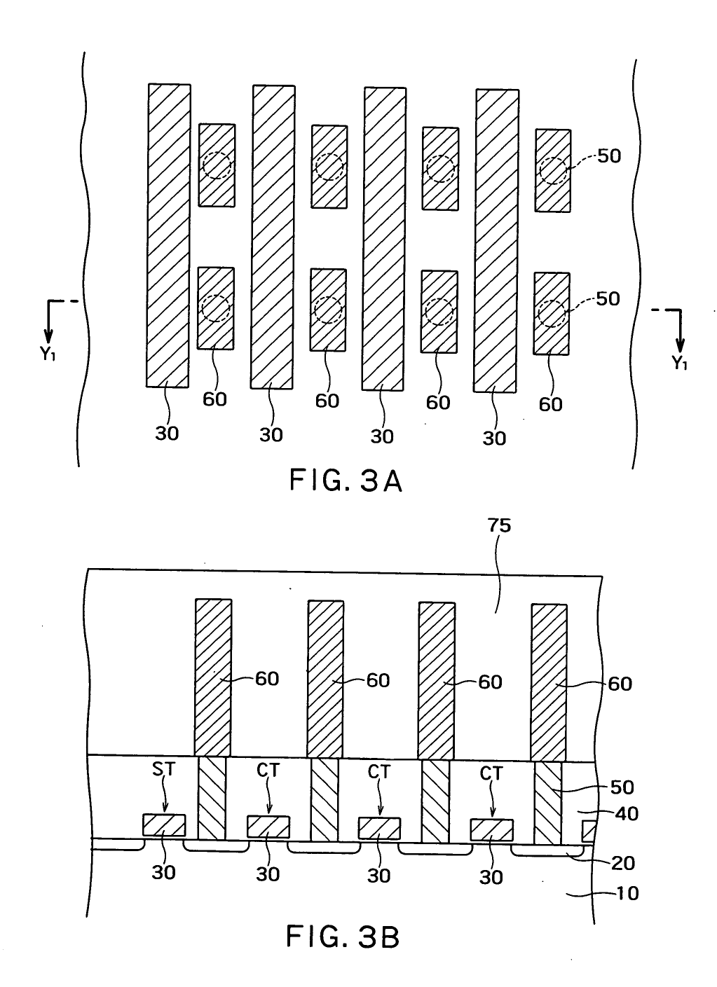

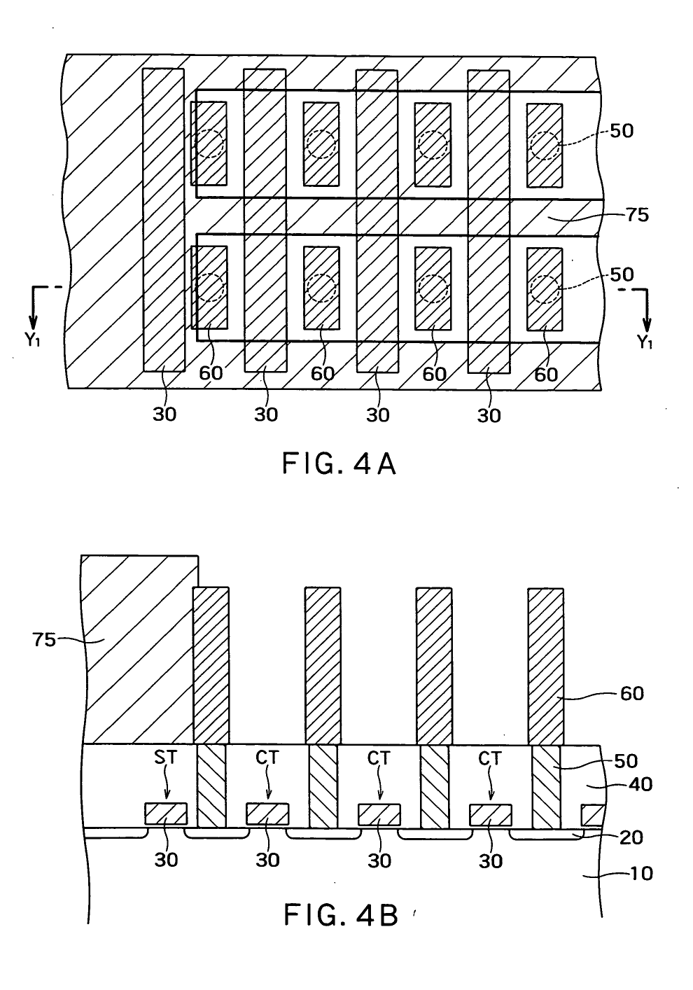

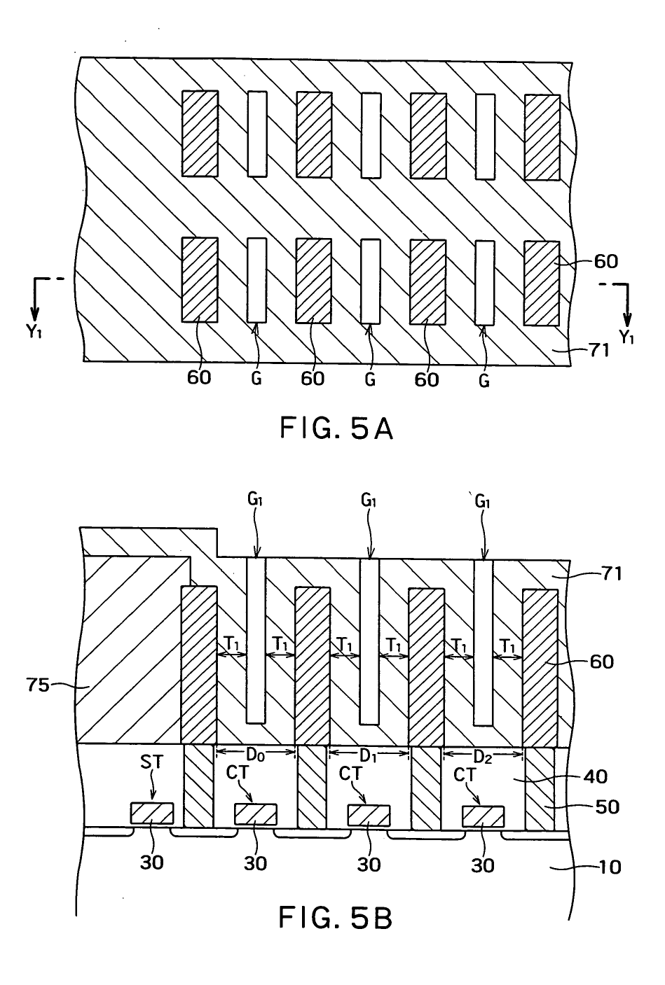

FIGS. 2A through 6 are a set of diagrams showing a flow of a manufacturing method of the FeRAM 100 according to the first embodiment. FIGS. 2A, 3A, 4A and 5A are plan views of the FeRAM 100 in different sequential steps. FIG. 2B is a cross-sectional view taken along the Y₁-Y₁ line of FIG. 2A. FIG. 3B is a cross-sectional view taken along the Y₁-Y₁ line of FIG. 3A. FIG. 4B is a cross-sectional view taken along the Y₁-Y₁ line of FIG. 4A. FIG. 5B is a cross-sectional view taken along the Y₁-Y₁ line of FIG. 5A.

As shown in FIGS. 2A and 2B, the cell transistors CT and the selector transistor ST are first formed on the semiconductor substrate 10. Thereafter, the interlayer insulating film 40 is deposited on the cell transistors CT and the selector transistor ST, and conductive plugs 50 are formed on the diffusion layers 20 by using polysilicon or tungsten.

After that, a material of capacitor electrodes 60 is deposited on the interlayer insulating film 40 and the plugs 50. In addition, capacitors 60 are formed on the plugs 50 by photolithography and RIE (Reactive Ion Etching). As shown in FIG. 1A, the capacitor electrodes 60 are divided to segments for individual cell blocks CB beforehand in the step of forming the capacitor electrodes 60. Distances D₀˜D₂ between neighboring capacitor electrodes 60 vary by 20˜30%.

In the next step shown in FIGS. 3A and 3B, an insulating film 75 is deposited between the capacitor electrodes 60.

In the next step shown in FIGS. 4A and 4B, the insulating film 75 is partly removed from around the capacitor electrodes 60 by photolithography and RIE. As a result, sidewalls of the capacitor electrodes 60 are exposed. In this step, the insulating film 75 is maintained between different cell blocks CB to prevent the capacitor electrodes 60 from short-circuiting between different cell blocks CB.

In the next step shown in FIGS. 5A and 5B, the ferroelectric film 71 is deposited on sidewalls of the capacitor electrodes 60 to an approximately uniform thickness T₁ by MOCVD (Metal Organic Chemical Vapor Deposition), or the like. Here is the requirement that the thickness T₁ of the ferroelectric film 71 is less than any of D₀/2, D₁/2 and D₂/2. Thus, the gaps G₁ are retained between capacitor electrodes 60.

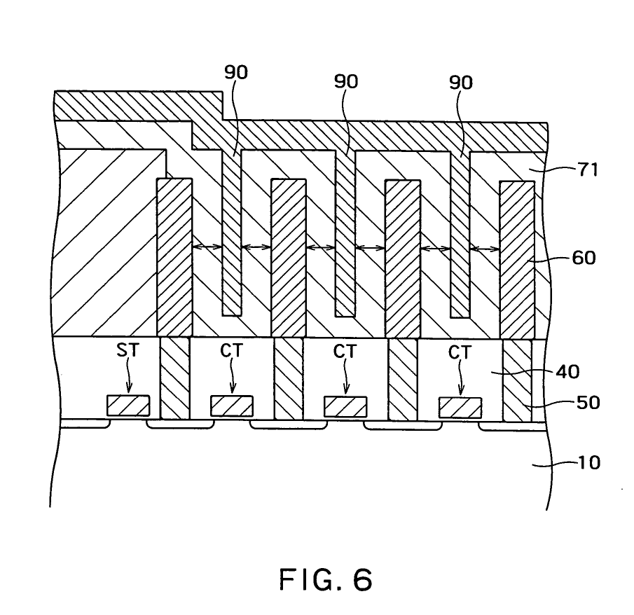

As shown in FIG. 6, a material for the floating electrodes 90 is deposited by MOCVD, or the like, to fill the gaps G₁ with it. Then, the material is planarized by etch-back technique or CMP to electrically isolate the individual floating electrodes 90. In this manner, the floating electrodes 90 are formed in self alignment. After that, a hydrogen barrier layer such as alumina may be deposited. Thereafter, as shown in FIG. 1B, by forming the interlayer insulating film 80, bit line contacts BLC, and bit lines BL, the FeRAM 100 is completed.

According to the embodiment, thickness T₁ of the ferroelectric film 71 depends upon the thickness of the film deposited in the step of depositing the ferroelectric film 71 as shown in FIG. 5B. The ferroelectric film 71, if deposited by MOCVD for example, varies only by 7% or less (about 5˜6%) of the expected value. Degree of this variation is much less than the variation of distances D_{0˜2} between capacitor electrodes 60 (approximately 20˜30%). Therefore, the ferroelectric film 71 between the capacitor electrodes 60 can be formed uniform in thickness in each capacitor CP₁. This results in approximately uniforming the quantity of polarization of the ferroelectric film 71 in data writing operation. Therefore, memory cells MC can store data uniformly.

According to the instant embodiment, the floating electrode 90 exists amid the ferroelectric film 71 in each capacitor CP₁. Therefore, thickness of the ferroelectric film 71 between the capacitor electrodes 60 is substantially 2*T₁. Since the thickness T₁ is less than ½ of the distance between the capacitor electrodes 60 as already explained, the substantial thickness 2*T₁ of the ferroelectric film 71 between the capacitor electrodes 60 is less than the distances D₀˜D₂ between the capacitor electrodes 60. As a result, the operation voltage for writing or erasure can be reduced from conventional values.

In the step of forming the capacitor electrodes 60 shown in FIG. 2A, the capacitor electrodes 60 are divided to segments for individual cell blocks CB beforehand. Therefore, the instant embodiment does not need to shape the capacitor electrodes 60, ferroelectric film 70 and floating electrodes 90 by etching in a later common step, and it is relatively easy to manufacture.

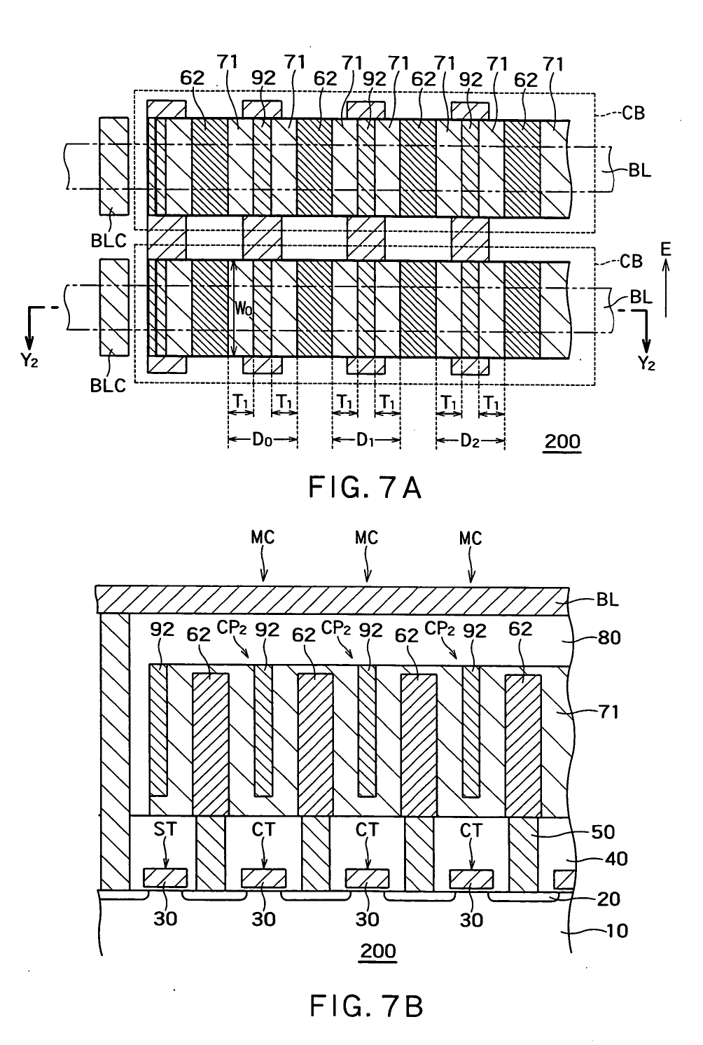

FIGS. 7A and 7B are a set of a plan view of a FeRAM 200 according to the second embodiment of the invention and a cross-sectional view thereof taken along the Y₂-Y₂ line on the plan view. The second embodiment is different from the first embodiment in width of each capacitor electrode 62 and width of each floating electrode 92 being equal to the width W₀ of the ferroelectric film 71. In the other respects, the second embodiment may be identical to the first embodiment.

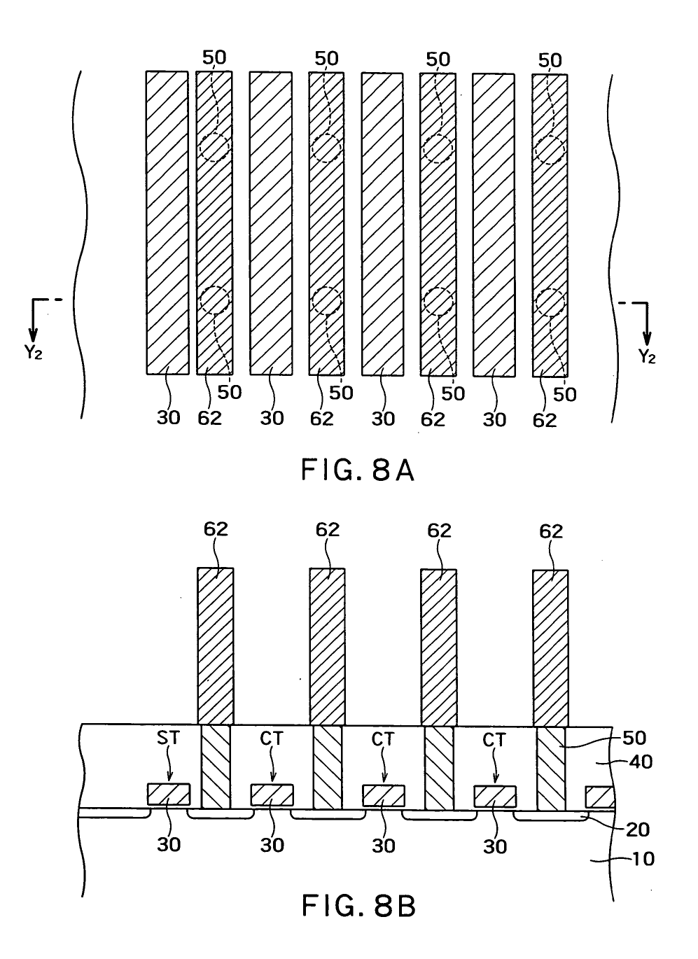

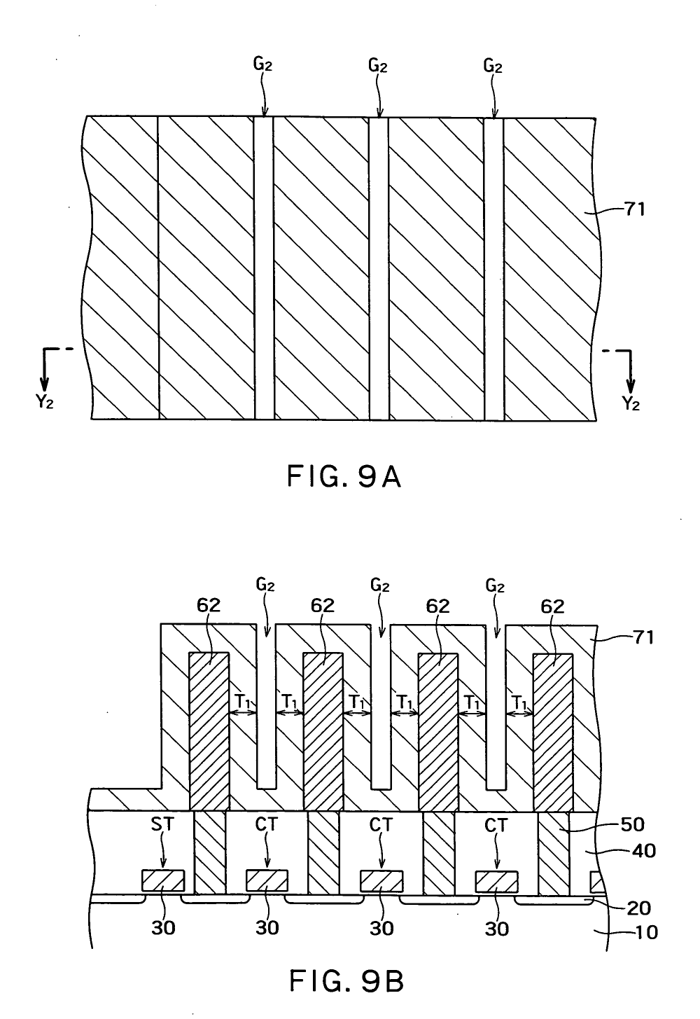

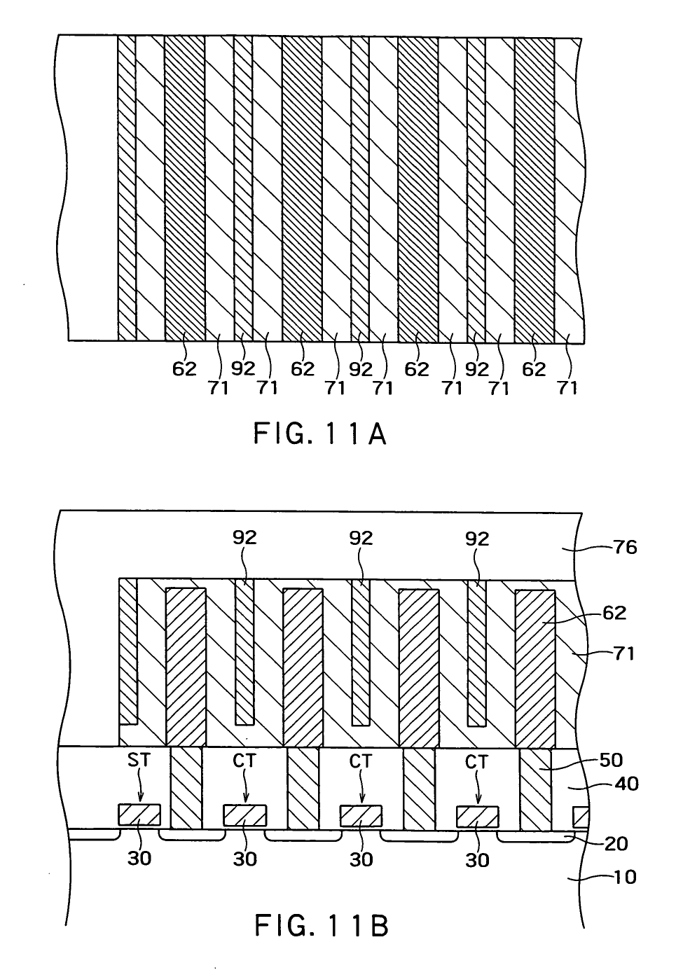

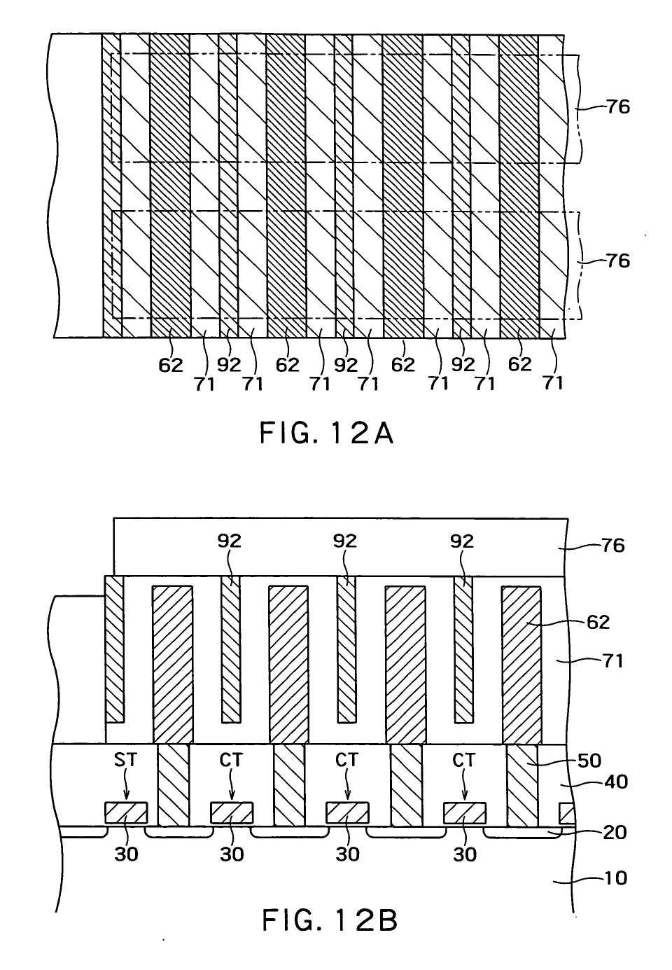

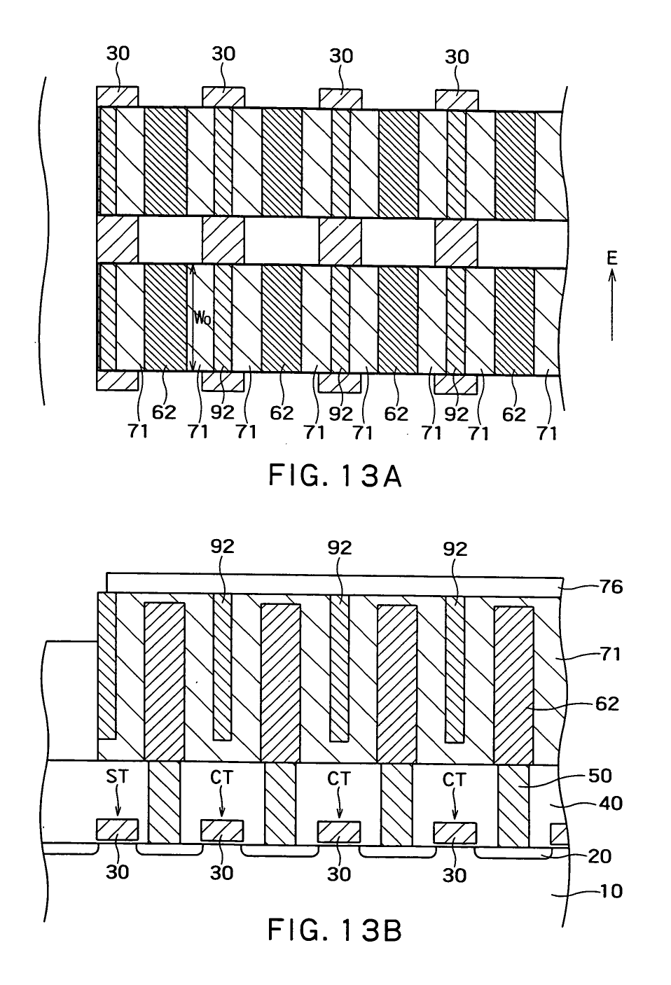

FIGS. 8A through 14 are a set of diagrams showing a flow of a manufacturing method of the FeRAM 200 according to the second embodiment. FIGS. 8A, 9A, 11A, 12A and 13A are plan views of the FeRAM 200 in different sequential steps. FIG. 8B is a cross-sectional view taken along the Y₂-Y₂ line of FIG. 8A. FIG. 9B is a cross-sectional view taken along the Y₂-Y₂ line of FIG. 9A. FIG. 11B is a cross-sectional view taken along the Y₂-Y₂ line of FIG. 11A. FIG. 12B is a cross-sectional view taken along the Y₂-Y₂ line of FIG. 12A. FIG. 13B is a cross-sectional view taken along the Y₂-Y₂ line of FIG. 13A.

As shown in FIGS. 8A and 8B, cell transistors CT and a selector transistor ST are first formed on the semiconductor substrate 10. Thereafter, an interlayer insulating film 40 is deposited on the cell transistors CT and the selector transistor ST, and conductive plugs 50 are formed on the diffusion layers 20.

In the next step, a material of capacitor electrodes 62 is deposited on the interlayer insulating film 40 and the plugs 50. Further, a material of the capacitor electrodes 62 is formed on the plugs 50 by photolithography and RIE. In this step, the capacitor electrodes 62 extend in parallel to word lines WL continuously over adjacent cell blocks CB as shown in FIG. 8A.

In the next step shown in FIGS. 9A and 9B, the ferroelectric film 71 is deposited on sidewalls of the capacitor electrodes 62 by an approximately uniform thickness T₁ by MOCVD or the like. Here is the requirement that the thickness T₁ of the ferroelectric film 71 is less than any of D₀/2, D₁/2 and D₂/2. Thus, the gaps G₂ are retained between capacitor electrodes 60.

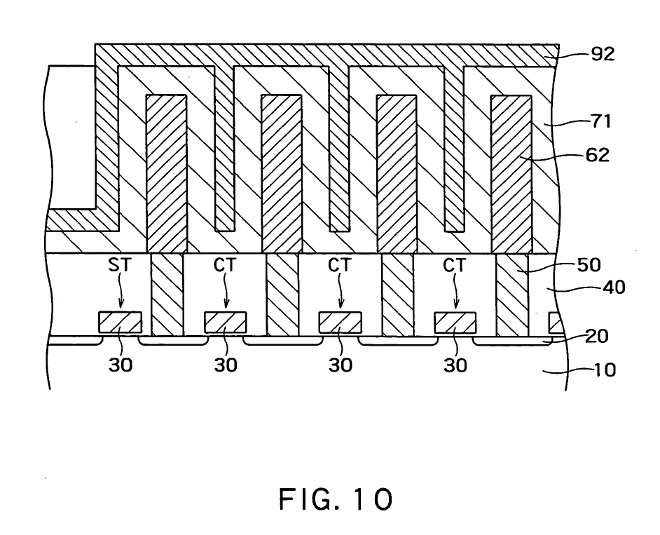

In the next step shown in FIG. 10, a material for the floating electrodes 92 is deposited by MOCVD, or the like, to fill the gaps G₂ with it.

In the next step shown in FIGS. 11A and 11B, the surface is planarized by etch-back technique or CMP. In this status, the material of the floating electrodes 92 is retained in the gaps G₂ and on the step portions. Thereafter, an insulating film 76 is deposited. The insulating film 76 is preferably made of an insulating material of an oxide film, such as DTEOS film, plasma silane, SOG film, or the like. The insulating film 76 is used as a mask in a later step.

In the next step shown in FIGS. 12A and 12B, the insulating film 76 is removed from gaps between cell blocks CB by photolithography and RIE. In this status, regions for cell blocks CB and bit line contacts BLC remain covered by the insulating film 76.

As shown in FIGS. 13A and 13B, under the existence of the insulating film 76 as a mask, the capacitor electrodes 62, ferroelectric film 71 and floating electrodes 92 are partly removed by etching using RIE. As a result, the capacitor electrodes 62, ferroelectric film 71 and floating electrodes 92 are divided to segments for individual cell blocks CB. The capacitor electrodes 62, ferroelectric film 71 and floating electrodes 92 have the equal width W₀ in the direction E.

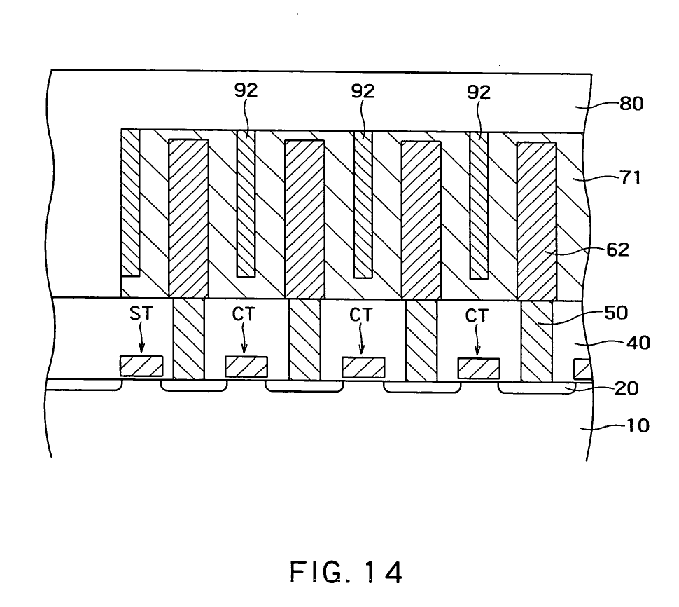

In the next step shown in FIG. 14, an interlayer insulating film 80 is deposited and planarized by CMP, for example. Before or after deposition of the interlayer insulating film 80, a hydrogen barrier film such as alumina may be deposited additionally. Thereafter, by forming the interlayer insulating film 80, bit line contacts BLC and bit lines BL as shown in FIG. 7B, the FeRAM 200 is completed.

According to the second embodiment, the capacitor electrodes 62, ferroelectric film 71 and floating electrodes 92 are divided to segments for individual cell blocks CB in a common step. As a result, all of the capacitor electrodes 62, ferroelectric film 71 and floating electrodes 92 are equalized in width to W₀ in the direction E. Therefore, the full width of ferroelectric film 71 in the direction E (widthwise direction) can be used for the capacitors CP₂ without any dead zone. That is, the second embodiment can increase the quantity of polarization of the ferroelectric film 71 in each capacitor CP2 relatively large.

Since the capacitor electrodes 62, ferroelectric film 71 and floating electrodes 92 are divided in a common step, there is no relative offset between the capacitor electrodes 62 and the floating electrodes 92. Therefore, the capacitors CP2 do not vary in capacitance.

Moreover, the second embodiment has the same effects as those of the first embodiment as well.

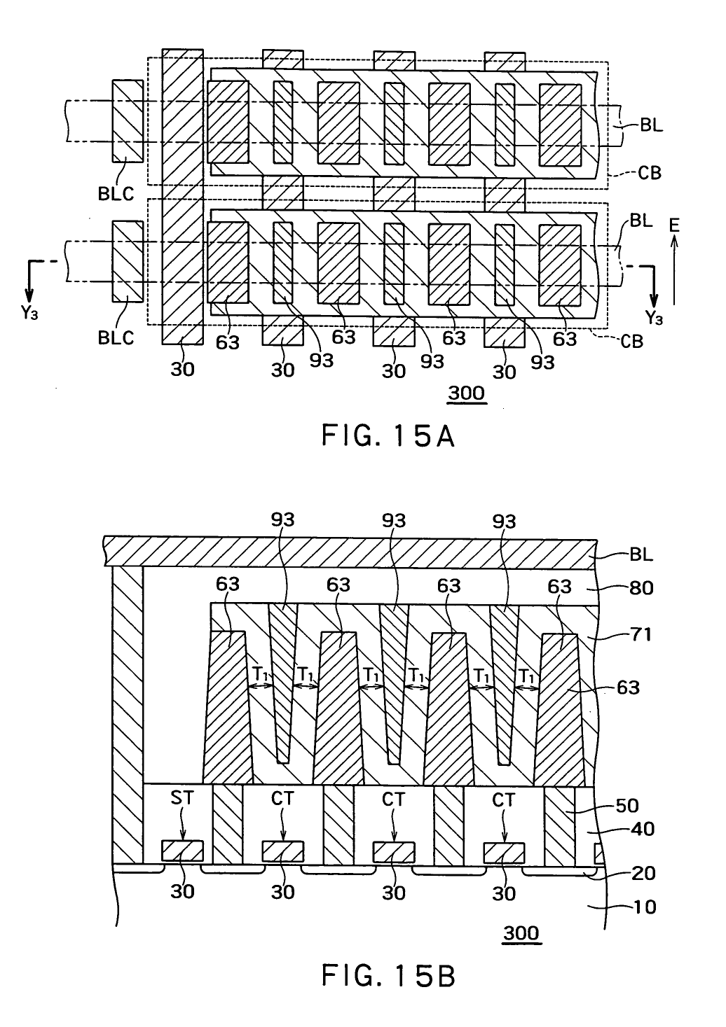

FIGS. 15A and 15B are a plan view of a FeRAM 300 according to the third embodiment of the invention and a cross-sectional view thereof taken along the Y₃-Y₃ line on the plan view. The third embodiment is different from the first embodiment in sidewalls of the capacitor electrodes 63 being tapered forward and sidewalls of the floating electrodes 93 being tapered oppositely. In the other respects, the third embodiment may be identical to the first embodiment.

Similarly, the manufacturing method of the third embodiment is different from the first embodiment in shaping sidewalls of the capacitor electrodes 30 in a forwardly tapered geometry. In the other respects, the manufacturing method according to the third embodiment may be identical to the manufacturing method of the first embodiment. Since the sidewalls of the capacitor electrodes 63 are tapered forward, the gaps G₁ appear in a tapered form (FIG. 5) after the ferroelectric film 71 is deposited. Therefore, even if the aspect ratio of the gaps G₁ is large, a material of floating electrodes 93 can fill the gaps G₁ more easily.

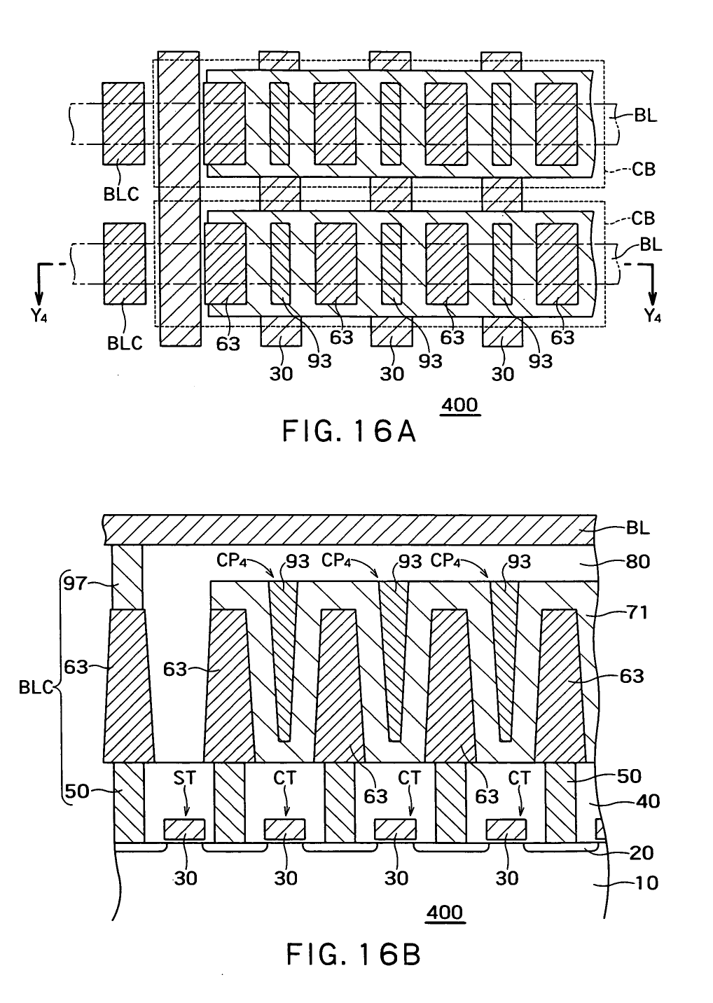

FIGS. 16A and 16B are a plan view of a FeRAM 400 according to the fourth embodiment of the invention and a cross-sectional view thereof taken along the Y₄-Y₄ line on the plan view. The fourth embodiment is different from the third embodiment in using plugs 50 and capacitor electrodes 63 as bit line contacts BLC. In the other respects, the fourth embodiment may be identical to the third embodiment.

By changing the mask patterns in the process of forming the plugs 50 and the process of forming capacitor electrodes 63, the plugs 50 and the capacitor electrodes 63 are additionally formed in the region for bit line contacts BLC. Therefore, it is sufficient for contact holes for contacts 97 to reach top surfaces of the capacitor electrodes 63, and it makes the process of forming bit line contacts BLC easier. Furthermore, since the etching time for forming the contact holes for the contacts 97 is shorter, characteristics deterioration of capacitors CP₄ near the bit line contacts BLC can be alleviated. Moreover, the fourth embodiment has the same effects as those of the third embodiment.

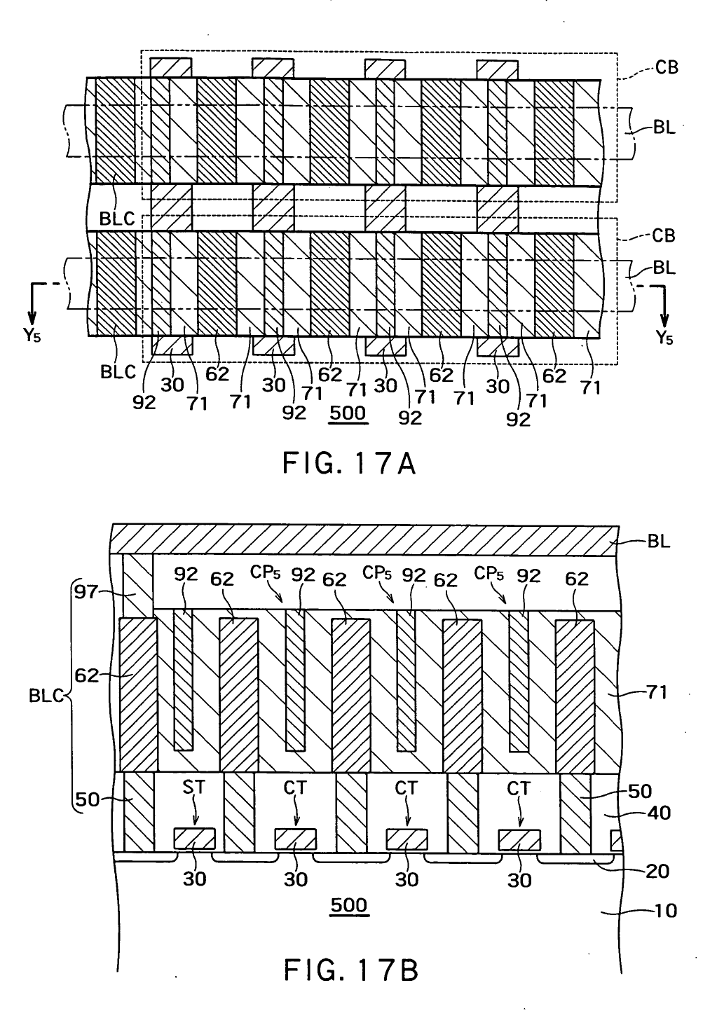

FIGS. 17A and 17B are a plan view of a FeRAM according to the fifth embodiment of the invention and a cross-sectional view thereof taken along the Y₅-Y₅ line on the plan view. The fifth embodiment is different from the second embodiment in using plugs 50 and capacitor electrodes 62 as bit line contacts BLC. In the other respects, the fifth embodiment may be identical to the second embodiment.

Similarly to the fourth embodiment, the fifth embodiment additionally forms plugs 50 and capacitor electrodes 62 in the region of bit line contacts BLC as well by changing mask patterns in the process for making plugs 50 and the process of making capacitor electrodes 62. Therefore, it is sufficient for contact holes for contacts 97 to reach top surfaces of the capacitor electrodes 63, and it makes the process of forming bit line contacts BLC easier. Furthermore, since the etching time for forming the contact holes for the contacts 97 is shorter, characteristics deterioration of capacitors CP₄ near the bit line contacts BLC can be alleviated. Moreover, the fifth embodiment has the same effects as those of the second embodiment.

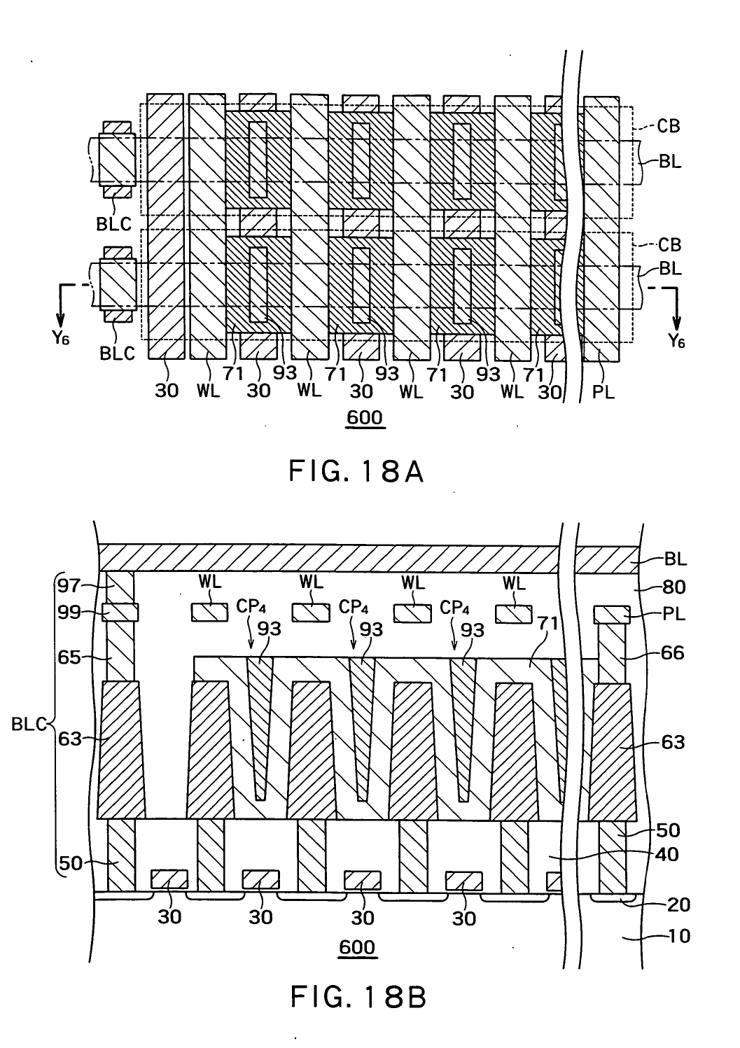

FIGS. 18A and 18B are a plan view of a FeRAM 600 according to the sixth embodiment of the invention and a cross-sectional view thereof taken along the Y₆-Y₆ line on the plan view. The sixth embodiment is different from the fourth embodiment in forming word lines WL and a plate line PL above the capacitors CP₄.

Each bit line contact BLC includes a pedestal 99 that is made of the same material as that of the word lines WL and the plate line PL simultaneously therewith in a common step. Contacts 65 and 97 are formed on and under the pedestal 99, and they connect the bit line contact BLC to a bit line BL.

The plate line PL is connected to the diffusion layer 20 at the opposite end of the cell block CB through a contact 66, which is formed simultaneously with the contact 65 in the common step, a capacitor electrode 63 and a plug 50. The word lines WL and the plate line PL extend substantially in parallel to the gate electrodes 30.

In the sixth embodiment, word lines WL, plate line PL, bit lines BL, capacitor electrodes 63 and bit line contacts BLC can be placed in a moderate layout without increasing the area of each cell block CB.

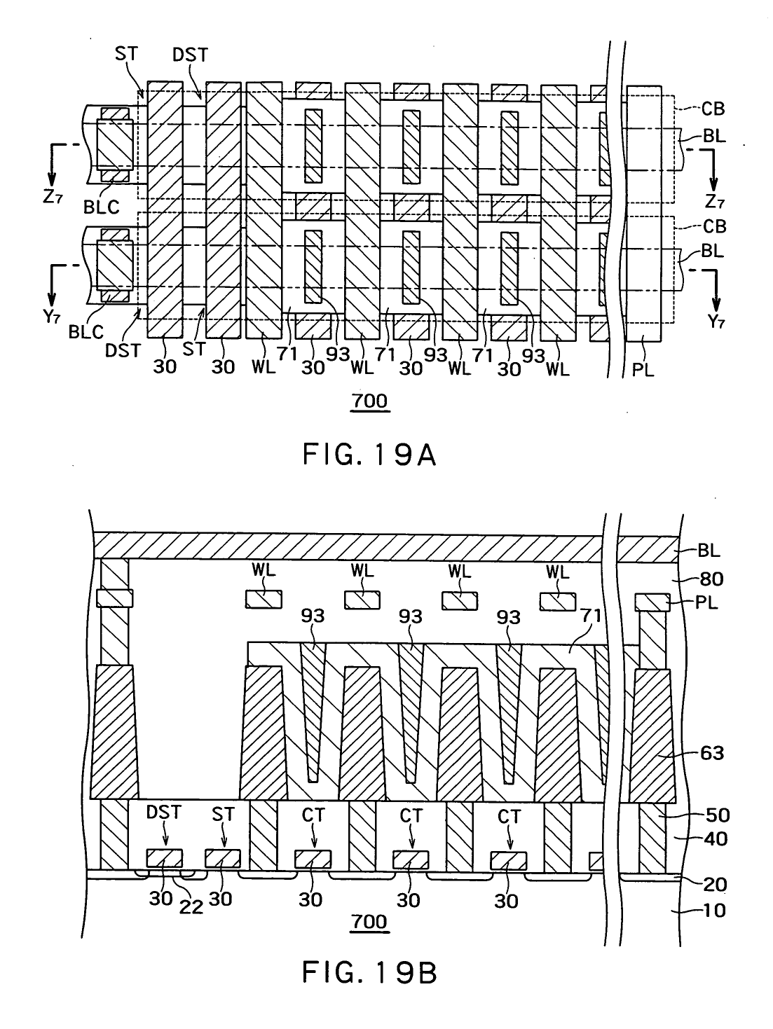

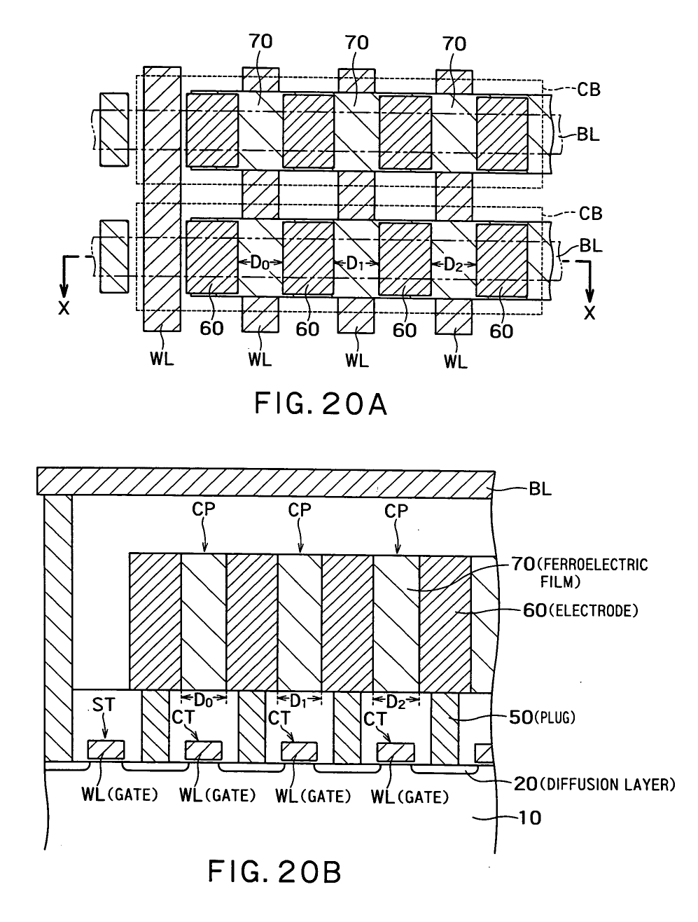

FIGS. 19A and 19B are a plan view of a FeRAM according to the seventh embodiment of the invention and a cross-sectional view thereof taken along the Y₇-Y₇ line on the plan view. The seventh embodiment is different from the sixth embodiment in placing the selector transistor in a folded layout.

The ninth embodiment includes two selector transistors ST and DST in each cell block CB. The selector transistor DST is formed as a depression-type transistor by the diffusion layer 22 and functions as a pass gate.

In a cross-sectional view taken along the Z₇-Z₇ line of FIG. 19A, the selector transistor ST and the selector transistor DST appear in opposite positions from each other. As a result, one of two neighboring cell blocks CB supply a data signal upon reading data, and the other supplies a reference signal for identifying the data signal. Therefore, the seventh embodiment assures reliable signal reading operation.

1. A semiconductor storage device comprising:
a semiconductor substrate;
a memory cell block including a plurality of transistors formed on the semiconductor substrate, said plurality of transistors being connected in series by serial connection of a source and a drain of two neighboring transistors;
first electrodes which are electrically connected to the source or drain of two neighboring transistors;
a ferroelectric film deposited on sidewalls of the first electrodes to retain a gap in a central portion between two neighboring first electrodes; and
second electrodes buried in the gaps and insulated from the electrodes of the transistors.

2. The semiconductor storage device according to claim 1, wherein
a width of the ferroelectric film is wider than the widths of the first electrodes and the second electrodes in the direction normal to the alignment direction of the plurality of transistors and parallel to a surface of the semiconductor substrate.

3. The semiconductor storage device according to claim 1, wherein
a width of the ferroelectric film is same as those of the first electrodes and the second electrodes in the direction normal to the alignment direction of the plurality of transistors and parallel to a surface of the semiconductor substrate.

4. The semiconductor storage device according to claim 1, wherein
a thickness of the ferroelectric film, which is provided on the first electrode, depends upon the thickness of the film deposited in the depositing process of the ferroelectric film.

5. The semiconductor storage device according to claim 4, wherein
the ferroelectric film is deposited by MOCVD.

6. The semiconductor storage device according to claim 4, wherein
a variation of the thickness of the ferroelectric film, which is provided on the first electrode, is 7% or less in the semiconductor storage device.

7. The semiconductor storage device according to claim 1, wherein
a thickness of the ferroelectric film, which is provided on the first electrode, is less than ½ of a distance between the neighboring first electrodes.

8. The semiconductor storage device according to claim 1, wherein
the first electrodes have sidewalls formed in a forward tapered shape,
wherein the ferroelectric film is deposited along with the sidewalls and has a gap in a central portion between the neighboring first electrodes,
wherein the second electrode is filled in the gap and is formed in an inverse tapered shape.

9. The semiconductor storage device according to claim 1 further comprising:
a bit line connected to a source or a drain of a transistor at an end of the memory cell block;
a plate line connected to a source or a drain of a transistor at the opposite end of the memory cell block; and
an interlayer insulating film provided on the ferroelectric film;
wherein the bit line is provided on the interlayer insulating film and is connected to a source or a drain of the transistor via a conductor, the conductor being made of a same material as the first electrodes.

10. The semiconductor storage device according to claim 1 further comprising:
a first interlayer insulating film provided on the ferroelectric film;
a word line provided on the first interlayer insulating film; and
a second interlayer insulating film provided on the word line;
wherein the bit line is provided on the second interlayer insulating film and is connected to a source or a drain of the transistor via a first conductor and a second conductor, the first conductor being made of a same material as the first electrodes, the second conductor being made of a same material as the word line.

11. The semiconductor storage device according to claim 1, wherein
a transistor at an end of the memory cell block is a selector transistor used to select the memory cell block,
wherein the memory cell block includes memory cells for 8 bits or 16 bits in addition to the selector transistor.

12. A manufacturing method of a semiconductor storage device, comprising:
forming a memory cell block including a plurality of transistors which are connected in series by connection of a source and a drain of neighboring transistors;
forming first electrodes connected to the source or the drain of neighboring transistors;
depositing a ferroelectric film on sidewalls of the first electrodes not to fill the space between the neighboring first electrodes but so as to retain a gap in a central portion between the neighboring first electrodes; and
burying the gaps with a second conductive material so that the second conductive material in each gap is insulated from the electrodes of the transistors.

13. The manufacturing method according to claim 12 further comprising:
dividing the first electrodes into segments for individual memory cell blocks in the process of forming the first electrodes;
depositing an insulating film between the memory cell blocks and between the first electrodes before depositing the ferroelectric film; and
selectively removing the insulating film between the first electrodes while retaining the insulating film between the memory cell blocks.

14. The manufacturing method according to claim 12, wherein
the first electrodes are formed serially between the memory cell blocks,
wherein, after filling the second conductor, the first electrodes, the second electrodes and the ferroelectric film are etched and are divided to segments for individual cell blocks.
